(19) United States
(12) Patent Application Publication
(10) Pub. No.: US 2002/0190664 A1
(43) Pub. Date: Dec. 19, 2002

(54) Organic EL element, organic EL element array and organic EL display

(75) Inventors: Haruo Tanaka, Kyoto-shi (JP); Chihaya Adachi, Chitose-shi (JP)

Correspondence Address: MERCHANT & GOULD PC, P.O. BOX 2903, MINNEAPOLIS, MN, 55402-0903, US

(73) Assignee: ROHM CO., LTD, Kyoto-shi (JP)

(21) Appl. No.: 10/131,494

(22) Filed: Apr. 24, 2002

(30) Foreign Application Priority Data
Apr. 25, 2001 (JP) 2001-128304

(51) Int. Cl. G09G 3/10

(52) U.S. Cl. 315/169.3

(57) ABSTRACT

An organic EL element includes: an anode layer; a cathode layer; at least one organic EL layer between the anode layer and the cathode layer; and a switching element capable of changing from a high-resistance state to a low-resistance state upon application of a voltage not smaller than a threshold value, capable of maintaining the low-resistance state when the applied voltage is decreased to a value smaller than the threshold value after the above state change, and connected in series to the organic EL layer.

### TECHNICAL FIELD

The present invention relates to an electro luminescent (EL) element, and more specifically to an organic EL element. The present invention further relates to an organic EL element array and an organic EL display each including the organic EL element as a display element.

### BACKGROUND OF THE INVENTION

In recent years, an organic EL element is a focus of attention as a display element. The organic EL element is a kind of EL elements known as self-emitting elements. The EL element includes a layer of a fluorescent or phosphorescent material. When an electric field is applied to this layer, a luminescence center of the material is excited to emit light. Depending upon whether the light emitting material in the light emitting layer is organic or inorganic, the EL element is classified as an organic EL element or an inorganic EL element.

The organic EL element and the inorganic EL element differ from each other in the state of excitation of their luminescence center and/or in their light emitting process. Due to these differences, the inorganic EL element is driven by an alternating current, whereas the organic EL element can be driven by a direct current. Further, in general, the organic EL element can be driven at a much lower voltage than the inorganic EL element. In addition, the organic EL element has a greater freedom for color differentiation, thus being suitable as a display element for color display.

Since the organic EL element is a self-emitting element, the organic EL display which uses the organic EL element can offer superior view provided by a wider angle of vision and a higher contrast than offered by e.g. a liquid crystal display that uses a liquid crystal element which is not self-emitting. Such an organic EL display does not require backlighting, and thus can easily be made thin and/or light-weighted, and is advantageous in terms of power consumption. Since the organic EL element has a short voltage response time, the organic EL display offers a superior image quality in displaying animations. Further, since organic EL element is entirely made of solid materials, the organic EL display has a wide temperature range in which the organic EL display can operate appropriately, and is not very sensitive to ruggedness. The organic EL display, having such advantageous features as the above, is suitable as a full color display device for a variety of TV sets, mobile phones and so on.

Conventional organic EL elements are generally classified into single-layer type, two-layer type or three-layer type depending upon the structure of a layer sandwiched between the electrodes. FIG. 6 shows a sectional structure of a conventional two-layer type organic EL element 100 formed on a substrate.

As shown in FIG. 6, the two-layer type organic EL element 100 includes an anode 101 formed on the substrate S, a hole transport layer 102 formed on the anode 101, a luminescent layer 103 formed subsequently thereon, and a cathode 104 formed subsequently thereon. The two-layer type organic EL element 100 does not have an independent electron transport layer, and electron transport is achieved through the luminescent layer 103. When a voltage is applied to the element 100, in a normal bias direction, i.e. a direction in which voltage reduction will occur from the anode 101 to the cathode 104, holes 105 are injected from the anode 101 into the hole transport layer 102. The injected holes 105 move through the hole transport layer 102 toward the luminescent layer 103. At the same time, electrons 106 are injected from the cathode 104 to the luminescent layer 103. The injected electrons 106 move through the luminescent layer 103 towards the hole transport layer 102. When the holes 105 and the electrons 106 recombine with each other in the luminescent layer 103, the luminescent layer 103 radiates light L. If the substrate S and the anode 101 are highly transparent, allowing visible light to pass through, then the light L radiated from the luminescent layer 103 comes through the anode 101 and the substrate S, out of the organic EL element 100.

As described above, the organic EL element 100 is a current-controlled electro luminescent element which is driven when a DC current is passed by an application of a voltage in the normal bias direction. Further, the conventional organic EL element 100 does not illuminate when the voltage is not applied. Specifically, the conventional organic EL element 100 itself does not have a memory capability in light emission, and this applies to all conventional organic EL elements of any layer type. In a display device made of display elements arranged in a matrix pattern to offer a pixel array, if the pixel array is to be driven as an active matrix, the memory capability with regard to the light emission must be given to each of the pixels. For this reason, in an organic EL display that includes a pixel array which is provided by the conventional organic EL elements not having the memory capability, in order for the pixel array to be driven as an active matrix, each pixel has to be provided with a relatively complex switching element such as a TFT (thin film transistor), and a capacitor element.

FIG. 7 is a fragmentary view of an electric circuit, showing part of a conventional organic EL display pixel array 200 including the organic EL element 100 in FIG. 6. Each unit pixel includes the organic EL element 100, a current controlling TFT 201 for controlling a current passing through the organic EL element, a capacitor 202 for holding an electric charge, and a switching TFT 203. Each unit pixel is connected with a scanning line 204 which is provided for each line of the pixel array, as well as being connected with a signal line 205 which is provided for each row of the pixel array. Further, each pixel is connected with a power source for driving the organic EL element via a power supply line 206, as well as being connected with a common cathode 207.

Now, let's take one unit-pixel P, which is enclosed by broken lines in the figure, for describing how the pixel array 200 can be driven as an active matrix.

First, one scanning line 204a is selected by an unillustrated scanning line driver, upon which all the switching TFTs 203 connected with the scanning line 204a are closed, i.e. switched ON, for a predetermined period of time. An unillustrated signal line driver outputs a predetermined voltage to a signal line 205b, thereby supplying a predetermined amount of electric charge to the capacitor 202 of the unit pixel P which is the pixel connected with the scanning line 204a and the signal line 205b, via the signal line 205b and the switching TFT 203. As a result, there develops an electric potential difference corresponding to the supplied charge, between the electrodes of the capacitor 202. The voltage between the electrodes of the capacitor 202 is supplied to between the gate and the source of the current controlling TFT 201. Thus, an electric current according to the gate-voltage/drain-current characteristic is supplied from the power supply line 206. This current passes through the TFT 201 and the organic EL element 100 to the common cathode 207. As a result, the organic EL element 100 illuminates in accordance with the amount of passing current. By causing the signal line driver to output the predetermined voltage to all of the signal lines 205 for the predetermined period of time for which the scanning line 204a is selected by the scanning line driver, a state of illumination is determined also for each of the other pixels connected with the scanning line 204a, in the same manner as described above for the pixel P.

After the predetermined time has passed since the selection of the scanning line 204a, the unillustrated scanning line driver deselects the scanning line 204a. When the scanning line 204a is deselected, the switching TFT 203 opens, i.e. turns OFF, but the electric potential difference between the electrodes of the capacitor 202 is maintained. Thus, until this inter-electrode potential is reset, there is a constant supply of current to the organic EL element 100 of the unit pixel P, and therefore the illumination of the element 100 is maintained.

After deselecting the scanning line 204a, the scanning line driver selects the next scanning line 204b, and the same steps as described above is repeated for each of the pixel lines connected to the scanning line 204b. By performing such a sequential line scanning for every pixel line in the pixel array, a complete image is formed, and by repeating such a sequential line scanning, the image is updated, resulting in an animation display.

Publications such as the Japanese Patent Laid-Open 4-70694, 7-111341 and 8-241048 disclose circuit constructions for driving, as an active matrix, a pixel array offered by conventional organic EL elements such as shown in FIG. 7. In any of the disclosed circuit constructions, each pixel is provided with a switching TFT and a capacitor in order to give the memory capability with regard to light emission of the organic EL elements.

As descried above, the conventional organic EL element does not have the memory capability within the element itself. Therefore, when manufacturing an active matrix organic EL, display, each EL element has to be provided with a micro switching element having a relatively complex structure, and a capacitor element, separately from the organic EL element, on the substrate. As a result, manufacturing process has to be long and complex, as well as expensive in terms of manufacturing cost. This problem is multiplied in manufacturing a large-screen display which requires a tremendously large number of pixels.

Further, in the conventional organic EL element active matrix display, each unit pixel requires a number of other elements than the organic EL element, which results in a complexity in timing control among relevant elements such as ON/OFF timing of the switching TFT, a charge supply time to the capacitor, and so on. Such a complexity in the control system also causes the manufacturing process to be complex and costly.

### DISCLOSURE OF THE INVENTION

The present invention aims at solving or reducing these conventional problems, and providing an organic EL element controllable as an element which has the memory capability within itself. The present invention also aims at providing an organic EL element array and an organic EL display each including such an organic EL element.

A first aspect of the present -invention provides an organic EL element. The organic EL element includes: an anode layer; a cathode layer; at least one organic EL layer between the anode layer and the cathode layer; and a switching element capable of changing from a high-resistance state to a low-resistance state upon application of a voltage not smaller than a threshold value, capable of maintaining the low-resistance state when the applied voltage is decreased to a value smaller than the threshold value after the above state change, and connected in series to the organic EL layer.

Such an organic EL element described as above can be controlled as having a memory capability, as will be described below. Specifically, first, when the switching element of the organic EL element assumes the high-resistance state, a first voltage which is smaller than a predetermined threshold value is applied. Under this state, the organic EL element passes a first electric current in accordance with the high-resistance state of the entire element and the first voltage. The predetermined threshold value is a sum of a voltage to be applied to the switching element itself in order for the switching element to switch, and voltages applied to the other elements, e.g. the organic EL layer of the element. The organic EL layer can include a luminescent layer, a carrier transport layer and carrier injection layer, and can have a variety of structures. The organic EL layer of the organic EL element according to the present invention can take any layer structure as long as the structure can function as an organic EL layer.

Next, the voltage applied to the entire organic EL element is increased to a predetermined value which is greater than the threshold value. Under this state, the switching element changes from the high-resistance state to the low-resistance state, allowing the organic EL element to pass an electric current in accordance with the low-resistance state of the entire element and the predetermined voltage exceeding the threshold value. Then, even if the applied voltage is simply decreased to the first voltage, which is smaller than the threshold value, the switching element maintains the low-resistance state,—allowing the organic EL element to pass a second electric current in accordance with the low-resistance state of the entire element and the first voltage. If the organic EL element emits light at a first luminance in accordance with the first current, and the organic EL element emits light at a second luminance in accordance with the second current, the second luminance is higher than the first luminance. This is due to a larger current passing through the luminescent layer under the same voltage applied, since the switching element, and therefore the entire element, has a smaller resistance.

As described above, luminance in light emission in the organic EL layer does not change in parallel with the change in voltage applied to the element. When an electric potential difference between the electrode layers is increased from the initial state to a value greater than the threshold value, and then simply decreased to the initial state, the light emission at the organic EL layer does not change from the initial state back to the initial state, but maintains a certain level of high luminance. In other words, the organic EL element according to the present invention can be controlled as having a memory capability.

The switching element can be made of an electrically conductive material which has a substantially wide difference in resistance between a high-resistance state and a low-resistance state. When such a material is used, accordingly, the second luminance becomes substantially higher than the first luminance. In such a case, the state of emission at the second luminance can be used as a luminescent state whereas the state of emission at the first luminance can be used as a virtually non-luminescent state. A luminescent state and a non-luminescent state can be differentiated alternatively. Specifically, when the switching element assumes the high-resistance state, a voltage applied to the luminescent layer of the organic EL layer is controlled to be smaller than a threshold voltage necessary for exciting the luminescence center of the luminescent layer, and on the other hand, when the switching element assumes the low-resistance state, the voltage applied to the luminescent layer of the organic EL layer is controlled to be equal or greater than the threshold voltage.

In order to make the EL element return to the initial state, i.e. in order to make the switching element return from the low-resistance state to the high-resistance state, a predetermined voltage pulse can be applied to the organic EL element, in a reverse bias direction. In this case, a threshold pulse voltage may have to be as high as the normal bias threshold voltage necessary for the switching element to change from the low-resistance state to the high-resistance state. Alternatively, the switching element can be returned to the high-resistance state by giving a zero-volt potential difference between the electrode layers of the organic EL element for a predetermined period of time.

As has been described, the organic EL element according to the first aspect of the present invention can be controlled as an element which has a memory capability within itself. Therefore, there is no need for providing e.g. TFTs and a capacitor separately from the organic EL element, when the organic EL element is required to have the memory capability, e.g. when the organic EL element is to be used as a display element for an organic EL display.

A second aspect of the present invention provides an organic EL element array. The organic EL element array includes: organic EL elements arranged in a matrix pattern of a plurality of lines and a plurality of rows; a plurality of first electrode wires each corresponding to one of the lines of the matrix of organic EL elements; and a plurality of second electrode wires each corresponding to one of the rows of the matrix of organic EL elements. The organic EL element includes: an anode layer; a cathode layer; an at least one organic EL layer between the anode layer and the cathode layer; and a switching element capable of changing from a high-resistance state to a low-resistance state upon application of a voltage not smaller than a threshold value, capable of maintaining the low-resistance state when the applied voltage is decreased to a value smaller than the threshold value after the above state change, and connected in series to the organic EL layer. Anode layers of the organic EL elements in a same line are communized by the first electrode wire corresponding to the line. Cathode layers of the organic EL elements in a same row are communized by the second electrode wire corresponding to the row.

A third aspect of the present invention provides an organic EL display. The organic EL display includes: organic EL elements arranged in a matrix pattern of a plurality of lines and a plurality of rows; a plurality of first electrode wires each corresponding to one of the lines of the matrix of organic EL elements; a plurality of second electrode wires each corresponding to one of the rows of the matrix of organic EL elements; a first driver for selectively giving an electric potential to the first electrode wires; and a second driver for selectively giving an electric potential to the second electrode wires. The organic EL element includes: an anode layer; a cathode layer; an at least one organic EL layer between the anode layer and the cathode layer; and a switching element capable of changing from a high-resistance state to a low-resistance state upon application of a voltage not smaller than a threshold value, capable of maintaining the low-resistance state when the applied voltage is decreased to a value smaller than the threshold value after the above state change, and connected in series to the organic EL layer. Anode layers of the organic EL elements in a same line are communized by the first electrode wire corresponding to the line. Cathode layers of the organic EL elements in a same row are communized by the second electrode wire corresponding to the row.

The second and the third aspects of the present invention provide an organic EL element array and an organic EL display which can be driven as an active matrix. Conventionally, in order to drive, as an active matrix, an organic EL element array incorporated in an organic EL display, each organic EL element must be provided with a micro switching element and a capacitor element, separately from the organic EL element, on the substrate. On the contrary, according to the present invention, there is no need for providing such other elements for each organic EL element, since each organic EL element of the array can be given a memory capability by a thin-film switching layer covering the entire panel in the same way as the organic EL layer. This advantage in making a pixel including an organic EL element is remarkable especially when manufacturing a large-screen, organic EL element array or organic EL display which requires a tremendously large number of pixels. According to the conventional organic EL element array, the number of switching elements and the capacitors increases as the area of the panel increases. On the contrary, according to the organic EL element array offered by the present invention, the number of switching layers to be formed is not dependent upon the area of the panel.

Further, according to the present invention, the entire organic EL element array can be driven as an active matrix, by directly controlling an electric potential difference between the electrodes of the organic EL element. Therefore, accuracy in driving control can be improved. As a result, it becomes possible to provide a high-quality image in the organic EL display.

According to the first through the third aspects of the present invention, preferably, the switching element is provided as a switching layer between the organic EL layer and the anode layer or the cathode layer. Alternatively, the switching element is preferably provided as a switching layer within the organic EL layer.

Preferably, the switching element includes an organic charge-transfer complex capable of changing from a high-resistance state to a low-resistance state upon application of a voltage not smaller than a threshold value and capable of maintaining the low-resistance state when the applied voltage is decreased to a value smaller than the threshold value after the above state change.

Preferably, the organic charge-transfer complex is provided by TCNQ or a metal complex of a TCNQ derivative.

According to the first through the third aspects of the present invention, preferably, the first and/or the second electrode wires are provided by ITO.

### BRIEF DESCRIPTION OF THE DRAWINGS

FIG. 1 is a fragmentary plan view of an organic EL element array according to a first embodiment of the present invention.

FIG. 2 is a sectional view taken in lines II-II in FIG. 1.

FIG. 3 is a fragmentary circuit diagram of the organic EL element array according to the first embodiment of the present invention.

FIG. 4 is a timing chart for describing how to drive an organic EL element array according to the present invention.

FIG. 5 is a fragmentary sectional view of an organic EL element array according to a second embodiment of the present invention.

FIG. 6 shows a sectional structure of a conventional organic EL element.

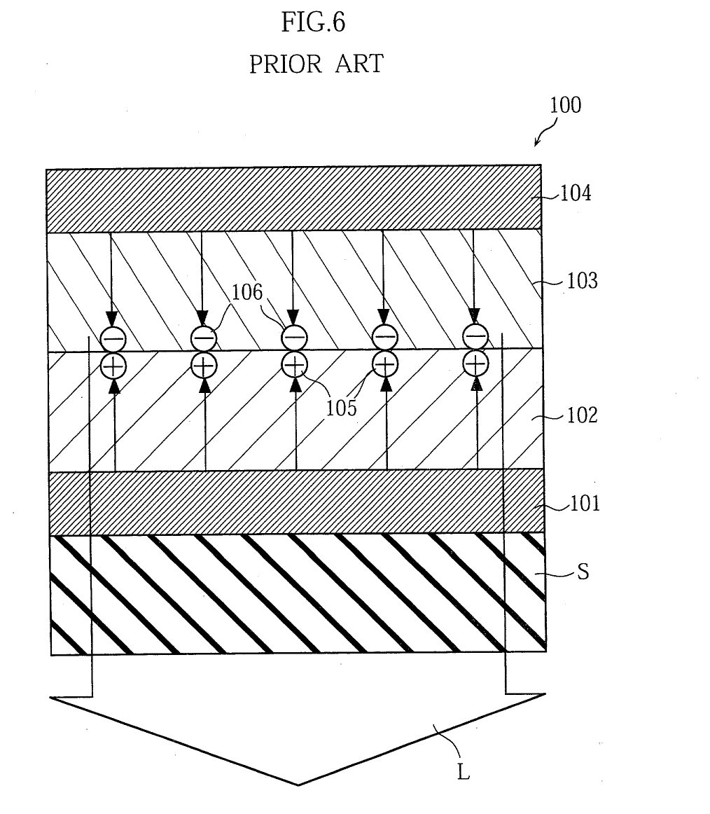

FIG. 7 is a fragmentary circuit diagram of a pixel array for a conventional organic EL display including the organic EL element shown in FIG. 6.

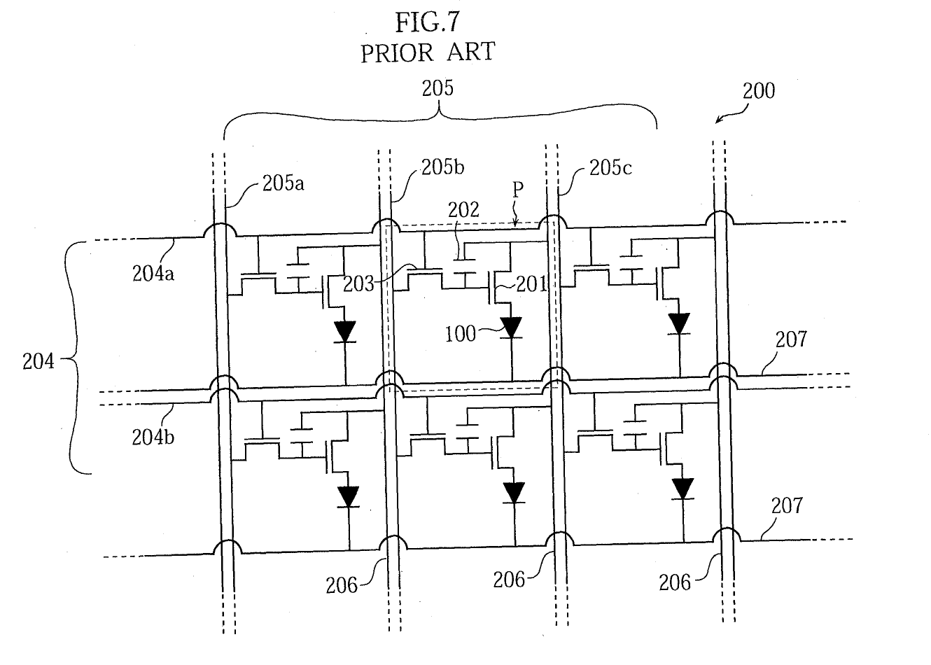

### BEST MODE FOR CARRYING OUT THE INVENTION

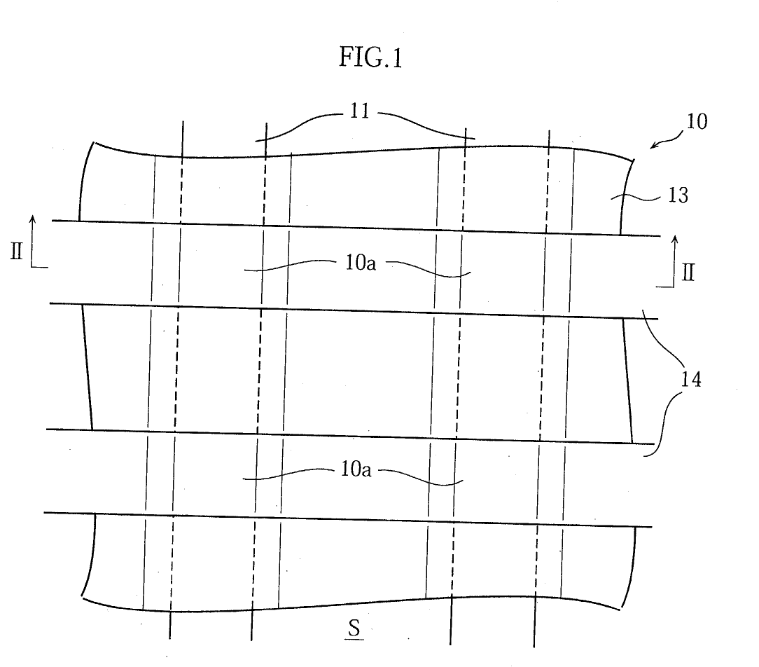

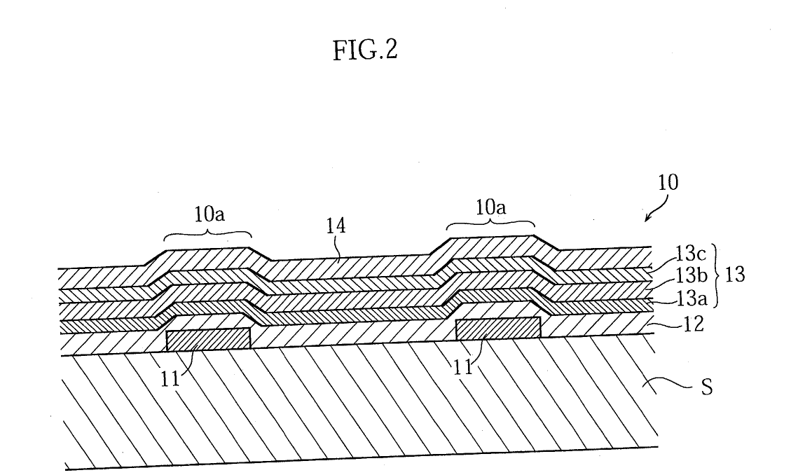

FIG. 1 is a fragmentary plan view of an organic EL element array 10 according to a first embodiment of the present invention. FIG. 2 is a sectional view taken in lines II-II in FIG. 1. The organic EL element array 10 includes a substrate S, a plurality of ITO electrode wires 11 each serving as an anode and spaced in parallel with each other on the substrate S, a switching layer 12 formed on the ITO electrode wires 11, an organic EL layer 13 formed on the switching layer 12, and a plurality of aluminum electrode wires 14 each serving as a cathode and spaced in parallel with each other on the organic EL layer 13. As shown in FIG. 2, according to the present embodiment, the organic EL layer 13 includes a hole transport layer 13a, a luminescent layer 13b and an electron transport layer 13c.

As shown in FIG. 1, the ITO electrode wires 11 and the aluminum electrode wires 14 are arranged in a grid pattern as in plan view, and are electrically connected with each other via the switching layer 12 and the organic EL layer 13. At each intersection made by the two kinds of electrode wires, there is formed an organic EL element 10a which includes a pair of electrodes 11, 14, the switching layer 12 and the organic EL layer 13. FIG. 1 shows a total of four organic EL elements 10a.

According to the present invention, the electrode wires can alternatively be made from materials other than ITO (indium-tin oxide) or aluminum. Such alternative materials include gold, copper iodide, tin oxide, magnesium, silver and lithium. The electrode wire through which the emitted light out of the luminescent layer 13b is preferably made of a highly transparent material that allows light to pass in the visible range, and therefore is more preferable if made of ITO as in the present embodiment.

The switching layer 12 is made of a copper complex of 7,7′,8,8′-tetra cyanoquinonedimethane (hereinafter abbreviated as TCNQ). The TCNQ copper complex is an organic charge-transfer complex, which changes its state from a high resistance state to a low resistant state when applied with a voltage not smaller than a threshold value, and can maintain the low resistance state if the above state change is followed by a voltage drop to a value smaller than the threshold value. According to the present invention, the TCNQ copper complex can be replaced by a material having a similar resistance characteristic, i.e. silver complex of TCNQ, a copper complex or a silver complex of a TCNQ derivative. Further, the switching layer 12 can be made of polypyrrole or a polymerized pyrrole derivative doped with TCNQ or containing TCNQ in a dispersed manner. These materials can also offer a similar resistance characteristic as offered by the TCNQ copper complex.

The hole transport layer 13a can be made of, e.g. 1,1-bis(4-di-p-aminophenyl) cyclohexane, triphenylamine and its derivatives, carbazole and its derivatives, as well as triphenylmethane and its derivaties. The electron transport layer 13c may be made of e.g. anthraquinodimethane, di-phenylquinone, perylene tetracarboxylic acid, triazole, oxazole, oxadiazole, benzoxazole and their respective derivatives. According to the present invention, a carrier transport layer can be provided by the hole transport layer and the electron transport layer as in the present embodiment, or may be provided by one of these.

The luminescent layer 13b can be made of a fluorescent or phosphorescent material such as tris(8-quinolinolato) aluminum complex, bis(benzo-quinolinolato)beryllium complex, tri(dibenzoyl methyl) phenanthroline europium complex, ditoluyl vinyl biphenyl and phenylpyridine iridium compound. Other materials which can be used includes light emitting polymers such as poly(p-phenylene vinylene), polyalkylthiophene, polyfluorene and their respective derivatives.

The substrate S can be provided by glass substrate such as barium borosilicate glass, aluminosilicate glass, quartz glass and Pyrex glass. By utilizing a transparent substrate capable of passing light of a predetermined range of wavelength, light emitted from the luminescent layer 13b can be taken out of the substrate S. Alternatively, the substrate S may be provided by a plastic substrate or a thin stainless-steel substrate having an optical-transparency. Further, the substrate S can be provided by a rigid material or a flexible material.

When manufacturing an organic EL element array 10 according to the present embodiment, first a vapor deposition or a sputtering process is performed to form an ITO film on the substrate S to a thickness of 300-2000 angstroms. The film, then, undergoes a patterning process, through which there is formed on the substrate S a plurality of ITO electrode wires 11 each running separately and in parallel with each other. An interval between mutually adjacent ITO electrodes is 10-100 micron meters.

Next, from above the ITO electrode wires 11, formation is made for a layer of TCNQ copper complex to cover the entire surface of the substrate S to a thickness of 0.1-10 micron meters, which will serve as a switching layer 12. The layer can be formed by a vacuum deposition such as electron beam deposition, resistance heating deposition and so on or sputtering, whereby the TCNQ copper complex is directly deposited on the substrate S formed with the ITO electrode wires. Alternatively, a vapor deposition method or a sputtering method can be employed to first form a film of copper on the substrate S, and then a vapor deposition method or a sputtering method can be employed again to form a film of TCNQ, and then this two-layer structure is heated at a temperature of 100-300 degrees centigrade for five minutes, to form a TCNQ copper complex near a border surface between these two layers. Further, alternatively, a vapor deposition method or a sputtering method can be employed to first form a film of copper on the substrate S, and then the entire substrate is submerged into a bath of TCNQ-saturated acetonitrile, whereby a TCNQ copper complex can be precipitated near the surface of the copper film.

Next, an organic EL layer 13 is formed on the switching layer 12 by sequentially forming, using a vacuum deposition method, a hole transport layer 13a having a thickness of 100-1000 angstroms, an luminescent layer 13b having a thickness of 100-1000 angstroms, and an electron transport layer 13chaving a thickness of 100-1000 angstroms. Alternatives to the vacuum deposition method include a gas phase crystal growth method, a spin coating method and a casting method. It should be noted here, however, that according to the present invention, alternatively to the layer structures described here, the switching layer 12 can be formed within the organic EL layer 13.

Next, on the organic EL layer 13, an aluminum film having a thickness of 500-1000 angstroms is formed by a vacuum deposition method, via a metal mask having a predetermined openings for formation of a plurality of aluminum electrode wires 14 running in parallel with each other at an interval of 10-100 micron meters on the organic EL layer 13.

The organic EL element array 10 thus made includes a plurality of the organic EL element 10a, each can be controlled to switch between two states, i.e. a luminescent and a virtually non-luminescent states. The switching layer 12 provided by the TCNQ cupper complex offers a switching function between the two stable states of a low-resistance state and a high-resistance state. The electrical resistance values in these states differ from each other by the order of 10-1000 times. Thus, the entire organic EL element 10a can assume the two distinct states with regard to electrical conductivity, i.e. conductive and virtually non-conductive states.

When the switching layer 12 is provided by TCNQ cupper complex of a thickness of 0.1-10 micron meters, the organic EL element 10a shows a resistance value of 1-10 mega ohms in the high-resistance state and 100-1000 ohms in the low-resistance state, with a threshold voltage of 1-12 volts. The threshold voltage according to the present embodiment means a voltage to be applied to the organic EL element 10a in order for the switching layer 12 to switch from the high-resistance state to the low-resistance state, and is a sum of electric potential differences occurring in the switching layer 12 and in the other layers of the organic EL element 10a.

According to the present embodiment, the electric resistance difference between the two states is large as described above. Therefore, the amount of electric current that passes through the element 10a is very small when a voltage smaller than the threshold value is applied in the normal bias direction of the element 10a if the switching layer 12 is in the high-resistance state. Here, the normal bias means an electric potential state in the element 10a in which electric potential at the anode 11 is higher than that of the cathode 14. As a result, the luminescent layer 13b in the element 10a is not excited, and therefore does not emit light. When a voltage not smaller than the threshold value is applied in the normal bias direction, the switching layer 12 changes its state from high-resistance to low-resistance, allowing a current of 1-100 mA/cm² to pass through the element 10a to excite the luminescence center of the luminescent layer 13b, thus causing light emission. The emitted light comes out of the element through the ITO electrode wires 11 and the substrate S which are highly transparent in the range of visible light.

The switching layer 12, which once has assumed the low-resistance state upon application of the voltage not smaller than the threshold value, does not return to the high-resistance state by simply reducing the applied normal bias voltage down to a value smaller than the threshold value. Specifically, the low-resistance state is maintained even if the applied voltage is smaller than the threshold value. For this reason, even after reducing the normal bias voltage application to a value smaller than the threshold value, a relatively large current continues to pass through the organic EL element 10a, and thus the element 10a continues to illuminate. In order to return to the high-resistance state, a voltage not smaller than a threshold value can be applied in a reverse bias direction, for example.

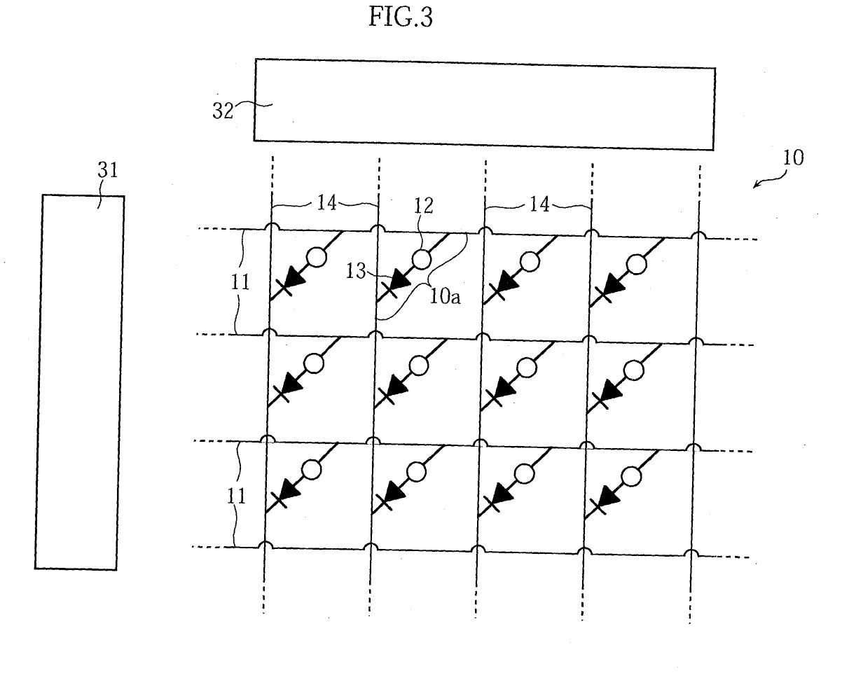

FIG. 3 is a fragmentary circuit diagram of the organic EL element array 10 according to the first embodiment of the present invention. Each of the ITO electrode wires 11 is electrically connected to a corresponding aluminum electrode wire 14 via the switching layer 12 and the organic EL layer 13. In other words, the anode layer of the organic EL element 10a is communized by the ITO electrode wires 11, whereas the cathode layer is communized by the aluminum electrode wires 14. As has been described, the switching layer 12 provides the switching function, and the organic EL layer 13 includes the luminescent layer 13b. An electrode wire driver 31 can supply a predetermined electric potential selectively to the ITO electrode wires 11. An electrode wire driver 32 can supply a predetermined electric potential selectively to the aluminum electrode wires 14. Therefore, through selective control by the electrode wire drivers 31, 32, the voltage applied to each of the organic EL element 10a is controlled, and whether the organic EL element illuminates or not is controlled. For the sake of simplicity, FIG. 3 does not show connections from the drivers to the electrode wires. As stated earlier, the organic EL element 10a according to the present embodiment can operate under a threshold voltage between 1-12 volts depending on the construction of organic EL layer 13b. For the sake of description, however, an assumption will be made that hereinafter, the organic EL element 10a has a threshold voltage of 5 volts.

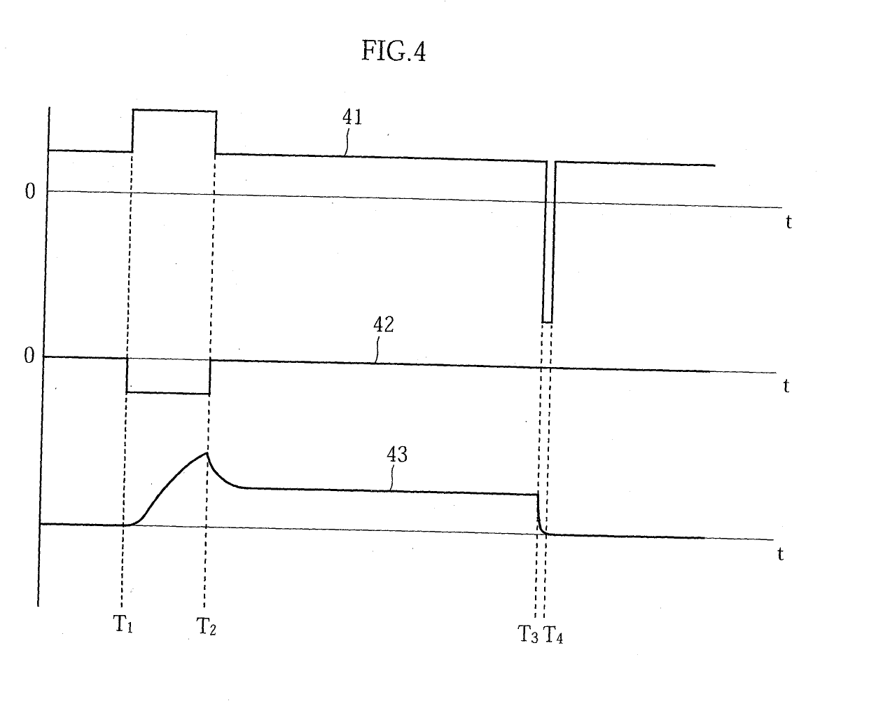

FIG. 4 is a timing chart for describing how to drive the organic EL element array 10. Graph 41 shows a time change of an anode potential in one ITO electrode wire 11 under a control by the electrode wire driver 31. Graph 42 shows a time change of a cathode potential in one aluminum electrode wire 14 under a control by the electrode wire driver 32. Graph 43 shows a time change of light emission status, expressed by the luminance, of an organic EL element 10a formed on an intersection made by these specific ITO electrode wire 11 and the aluminum electrode wire 14.

At an initial state (t=0), the switching layer 12 of the organic EL element 10a assumes the high-resistance state. The ITO electrode wires 11 serving as the anode is given a voltage of 3 volts for example, whereas the aluminum electrode wires 14 serving as the cathode is given a voltage of 0 volt for example. Under this state, an inter-electrode voltage, or a potential difference between the electrodes in the organic EL element 10a is 3 volts, which is smaller than the threshold voltage of 5 volts. Thus, the switching layer 12 maintains the high-resistance state, allowing only a very small amount of current to pass through the organic EL layer 13 of the organic EL element 10a. Therefore, the luminescent layer 13b does not illuminate.

When t=T₁, under a control from the electrode wire driver 31, an anode potential 41 is increased to e.g. 5 volts, and the potential is maintained until t=T₂. Meanwhile, under a control from the electrode wire driver 32, a cathode potential 42 is decreased to e.g. −2 volts, and this potential is maintained until t=T₂. Under this state, the potential difference between the electrodes in the organic EL element 10a is 7 volts, which is greater than the threshold voltage of 5 volts. Thus, the switching layer 12 changes its state from the high-resistance state to the low-resistance state, allowing a relatively very large amount of current to pass through the organic EL layer 13. As a result, luminescence center of the luminescent layer 13b is excited to illuminate.

Then, when t=T₂, the anode potential 41 is again decreased to 3 volts, and corresponding to this, the cathode potential 42 is returned to 0 volt. Under this state, the potential difference between the electrodes in the organic EL element 10a is 3 volts, which is smaller than the threshold voltage of 5 volts. However, since the switching layer 12 maintains the low-resistance state, allowing the relatively very large amount of current, which corresponds to the 3-volt potential difference, to pass through the organic EL layer 13. As a result, luminescence center of the luminescent layer 13b continues to be excited to keep illuminating at a predetermined luminance. In other words, the potential values in both of the electrode wires have already returned to those of the initial state, but the organic EL element 10a is not yet returned to its initial state.

Then, when t=T₃, the cathode potential 42 is maintained at 0 volt, whereas the anode potential 41 is decreased to e.g. −6 volts. Under this state, the potential difference between the electrodes in the organic EL element 10a is 6 volts, or there is a voltage not smaller than the threshold voltage of 5 volts being applied in the reverse bias direction of the organic EL element 10a. This electric impact causes the switching layer 12 to change its state from the low-resistance state to the high-resistant state, allowing now only a very small amount of electric current to pass through the organic EL layer 13. As a result, the excitation at the luminescence center of the luminescent layer 13b ceases, and the organic EL element 10a assumes the non-illuminating state.

In FIG. 4, the potential difference after t=T₄ is 3 volts, or the same as of the initial state, and the organic EL element 10a assumes the non-illuminating state. If it is desired that the organic EL element 10a being referenced in FIG. 4 illuminate further, then, starting from t=T₄, the above-described control from t=T₁ is repeated to the corresponding ITO electrode wire 11 and the aluminum electrode wire 14.

At the point of t=T₂, the electrode wire driver 31 will then apply the predetermined voltage to the next ITO electrode wire 11, and then to the following ITO electrode wire 11 each time a predetermined amount of time passes. While one ITO electrode wire 11 is selected (T₁-T₂), the driver 32 gives its voltage application control to this particular ITO electrode wire 11, thereby allowing each of the organic EL elements 10a within this particular line to assume the luminescent or the non-luminescent state. By performing such a sequential line scanning for all of the pixel lines in the array 10a, a complete image can be formed. Further, by repeating such a sequential line scanning, the image can be updated to display an animation. It should be noted however, that the cathode potential 42 shown in FIG. 4 will be controlled to 0 volt after T₂, in view of simplification.

As has been described, the organic EL element array 10 according to the present invention uses a circuit construction similar to that of a passive matrix type, but virtually can be driven as an active matrix.

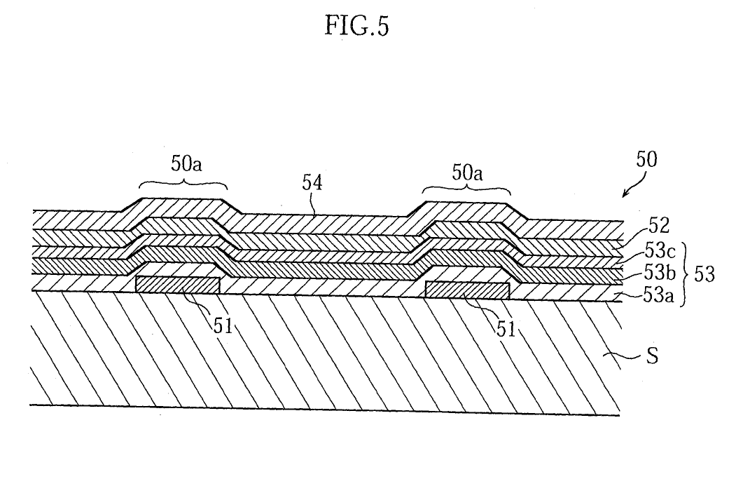

FIG. 5 is a fragmentary sectional view of an organic EL element array 50 according to a second embodiment of the present invention. The figure corresponds to FIG. 2 of the first embodiment. According to the present embodiment, the organic EL element array 50 includes a substrate S, a plurality of ITO electrode wires 51 each serving as an anode and spaced in parallel with each other on the substrate S, an organic EL layer 53 formed on the ITO electrode wires 51, a switching layer 52 formed on the organic EL layer 53, and a plurality of aluminum electrode wires 54 each serving as a cathode and spaced in parallel with each other on the switching layer 12. According to the present embodiment, organic EL layer 53 includes a hole transport layer 53a, a luminescent layer 53b and an electron transport layer 53c.

According to the an organic EL element 50a offered by the present embodiment, the hole transport layer 53a is connected directly with the ITO electrode layer 51 serving as the anodes, and the switching layer 52 is provided between the electron transport layer 53c and the aluminum electrode wires 54 serving as cathodes. Other aspects of construction are the same as of the first embodiment.

In the organic EL element 50a according to the present embodiment, the switching layer and the organic EL layer are arranged in series in the element, as in the organic EL element 10a according to the first embodiment. Therefore, the organic EL element 50a offers the same function as offered by the organic EL element 10a according to the first embodiment, and can be controlled by a method similar to the method described earlier for the first embodiment with reference to FIG. 4.

An organic EL display can be made by using the organic EL element array 10 or 50 described above. The organic EL display according to the present invention can be made for monochrome display or color display. When manufactured for color display by using a color filter or a color conversion layer, the color filter layer or the color conversion layer is provided between the anode and the glass substrate. Alternatively, the color display can be achieved by preparing three kinds of the organic EL element each having a luminescent layer for one of the three primary colors or one quasi-color of the three primary colors. The three kinds of organic EL elements for the different colors are arranged closely to each other in the display element array.

In the above embodiments, description was made for organic EL elements having an arrangement for the emitted light to come out through an optically transparent anode and a glass substrate. It should be noted here that the present invention includes an organic EL element having an arrangement for the emitted light to come out through an optically transparent cathode and a glass substrate provided on the cathode side.

Further, according to the above embodiments, the organic EL layer has a three-layer structure, including a hole transport layer, a luminescent layer and an electron transport layer. However, the present invention is not limited to such a layer structure. For example, the organic EL layer may only have a luminescent layer, or a carrier transport layer may be provided separately. Further, switching layer may be provided within the organic EL layer.

1. An organic EL element including:
an anode layer; a cathode layer;
at least one organic EL layer between the anode layer and the cathode layer; and
a switching element capable of changing from a high-resistance state to a low-resistance state upon application of a voltage not smaller than a threshold value, capable of maintaining the low-resistance state when the applied voltage is decreased to a value smaller than the threshold value after the above state change, and serially connected to the organic EL layer.

2. The organic EL element according to claim 1, wherein the switching element is provided as a switching layer between the organic EL layer and the anode layer or the cathode layer.

3. The organic EL element according to claim 1, wherein the switching element is provided as a switching layer within the organic EL layer.

4. The organic EL element according to claim 1, wherein the switching element includes an organic charge-transfer complex capable of changing from a high-resistance state to a low-resistance state upon application of a voltage not smaller than a threshold value and capable of maintaining the low-resistance state when the applied voltage is decreased to a value smaller than the threshold value after the above state change.

5. The organic EL element according to claim 4, wherein the organic charge-transfer complex is provided by TCNQ or a metal complex of a TCNQ derivative.

6. An organic EL element array including:
organic EL elements arranged in a matrix pattern of a plurality of lines and a plurality of rows;
a plurality of first electrode wires each corresponding to one of the lines of the matrix of organic EL elements; and
a plurality of second electrode wires each corresponding to one of the rows of the matrix of organic EL elements; wherein
the organic EL element includes: an anode layer; a cathode layer; an at least one organic EL layer between the anode layer and the cathode layer; and a switching element capable of changing from a high-resistance state to a low-resistance state upon application of a voltage not smaller than a threshold value, capable of maintaining the low-resistance state when the applied voltage is decreased to a value smaller than the threshold value after the above state change, and connected in series to the organic EL layer,
anode layers of the organic EL elements in a same line being communized by the first electrode wire corresponding to the line,
cathode layers of the organic EL elements in a same row being communized by the second electrode wire corresponding to the row.

7. The organic EL element array according to claim 6, wherein the first and/or the second electrode wires are provided by ITO.

8. The organic EL element array according to claim 6, wherein the switching element is provided as a switching layer between the organic EL layer and the anode layer or the cathode layer.

9. The organic EL element array according to claim 6, wherein the switching element is provided as a switching layer within the organic EL layer.

10. The organic EL element array according to claim 6, wherein the switching element includes an organic charge-transfer complex capable of changing from a high-resistance state to a low-resistance state upon application of a voltage not smaller than a threshold value and capable of maintaining the low-resistance state when the applied voltage is decreased to a value smaller than the threshold value after the above state change.

11. The organic EL element according to claim 10, wherein the organic charge-transfer complex is provided by TCNQ or a metal complex of a TCNQ derivative.

12. An organic EL display including:
organic EL elements arranged in a matrix pattern of a plurality of lines and a plurality of rows;
a plurality of first electrode wires each corresponding to one of the lines of the matrix of organic EL elements;
a plurality of second electrode wires each corresponding to one of the rows of the matrix of organic EL elements;
a first driver for selectively giving an electric potential to the first electrode wires; and
a second driver for selectively giving an electric potential to the second electrode wires; wherein
the organic EL element includes: an anode layer; a cathode layer; an at least one organic EL layer between the anode layer and the cathode layer; and a switching element capable of changing from a high-resistance state to a low-resistance state upon application of a voltage not smaller than a threshold value, capable of maintaining the low-resistance state when the applied voltage is decreased to a value smaller than the threshold value after the above state change, and connected in series to the organic EL layer,
anode layers of the organic EL elements in a same line being communized by the first electrode wire corresponding to the line,
cathode layers of the organic EL elements in a same row being communized by the second electrode wire corresponding to the row.

13. The organic EL display according to claim 12, wherein the first and/or the second electrode wires are provided by ITO.

14. The organic EL display according to claim 12, wherein the switching element is provided as a switching layer between the organic EL layer and the anode layer or the cathode layer.

15. The organic EL display according to claim 12, wherein the switching element is provided as a switching layer within the organic EL layer.

16. The organic EL display according to claim 12, wherein the switching element includes an organic charge-transfer complex capable of changing from a high-resistance state to a low-resistance state upon application of a voltage not smaller than a threshold value and capable of maintaining the low-resistance state when the applied voltage is decreased to a value smaller than the threshold value after the above state change.

17. The organic EL display according to claim 12, wherein the organic charge-transfer complex is provided by TCNQ or a metal complex of a TCNQ derivative.
